(19) United States
(12) Patent Application Publication
(10) Pub. No.: US 2003/0089457 A1
(43) Pub. Date: May 15, 2003

(54) Apparatus for controlling a thermal conductivity profile for a pedestal in a semiconductor wafer processing chamber

(75) Inventors: Padmapani C. Nallan, San Jose, CA (US); Ajay Kumar, Sunnyvale, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/993,240

(22) Filed: Nov. 13, 2001

(51) Int. Cl. C23C 16/00; C23F 1/00; H01L 21/306; B05C 13/00

(52) U.S. Cl. 156/345.51; 156/345.52; 156/345.53; 118/724; 118/725; 118/500; 118/728

(57) ABSTRACT

Apparatus for controlling a thermal conductivity profile of a pedestal in a semiconductor wafer processing system. One embodiment of the apparatus is a thermal shim that is positioned between a wafer retention device (e.g., electrostatic chuck) and a pedestal. The shim controls the thermal conductivity between the wafer retention device and the pedestal. In one embodiment, the thermal shim has a low thermally conductive region and a high thermally conductive region. In a further embodiment, the low thermally conductive region is a hole. By having a hole in the center of the shim, thus forming an annulus, an air gap is formed between the wafer retention device and the pedestal such that less heat will be transferred through the air gap as compared to the high thermally conductive region of the shim.

### BACKGROUND OF THE INVENTION

1. Field of the Invention

The present invention generally relates to semiconductor wafer processing chambers and, more particularly, to a apparatus for controlling the thermal conductivity profile through a wafer support pedestal within semiconductor wafer processing chambers.

2. Description of the Related Art

When processing a semiconductor wafer within certain types of semiconductor wafer processing chambers, e.g., a plasma etch reactor, the wafer experiences a substantial amount of heating. To control the wafer temperature, the wafer is supported upon a pedestal within the plasma reactor and the pedestal generally contains a heat exchanger element to remove heat from the pedestal. The wafer is retained on the pedestal using a retaining mechanism such as an electrostatic chuck.

To facilitate heat transfer from the electrostatic chuck to the pedestal upon which the chuck is mounted, a thin foil film is placed between the electrostatic chuck and the pedestal. The electrostatic chuck is bolted to the pedestal with the foil sandwiched between the chuck and the pedestal such that heat is transferred from the chuck to the pedestal and, ultimately, to the heat exchanger that removes the heat. The goal is to maintain the wafer at a constant temperature across the entire wafer. However, in a typical plasma reactor, the temperature profile across the wafer is such that the center of the wafer is cooler than the edges. Such a temperature profile causes a variation in the wafer processing from center to edge of the wafer. In an etch process, this non-uniform temperature profile causes the center trenches to be more vertical and narrower than the edge trenches. In some instances, the edge trenches may have widths that are 40 percent larger than the center trenches.

Therefore, there is a need in the art for apparatus to control the thermal conductivity profile of a wafer support pedestal within a semiconductor wafer processing chamber.

### SUMMARY OF THE INVENTION

The disadvantages associated with the prior art are overcome by placing a thermal shim between a wafer retention device (e.g., electrostatic chuck) and a pedestal. The shim controls the thermal conductivity between the wafer retention device and the pedestal. In one embodiment, the thermal shim comprises a low thermally conductive region and a high thermally conductive region. In a further embodiment, the low thermally conductive region is a hole. By having a hole in the center of the shim, thus forming an annulus, an air gap is formed between the wafer retention device and the pedestal such that less heat will be transferred through the air gap as compared to the high thermally conductive region of the shim. Consequently, the center of the wafer will be slightly warmer and the edges slightly cooler than a wafer using a prior art arrangement. As such, the thermal profile of the wafer surface is more uniform than has been previously available.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 depicts a schematic cross-sectional, schematic view of a plasma etch reactor that utilizes one embodiment of the present invention;

FIG. 2 depicts an exploded view of a wafer support pedestal that includes one embodiment of the present invention; and

FIG. 3 depicts a thermal conductivity control shim in accordance with one embodiment of the present invention.

### DETAILED DESCRIPTION

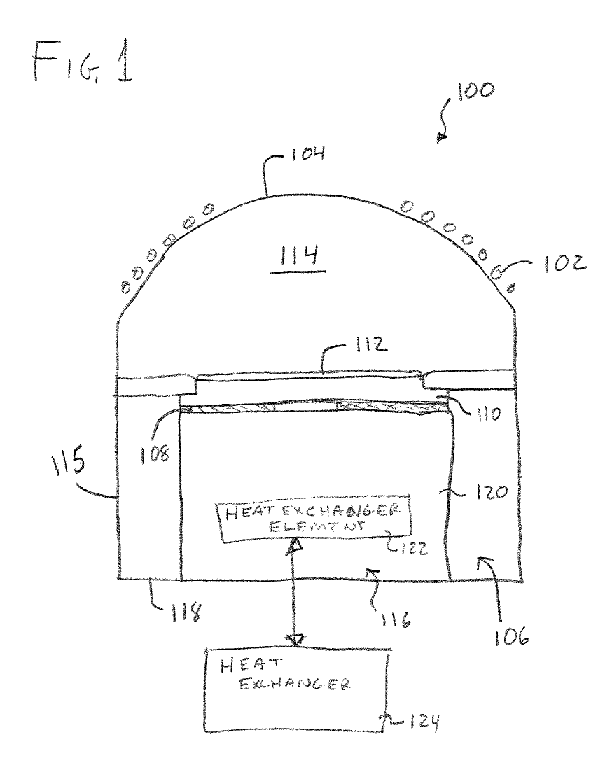

FIG. 1 depicts a particular example of a semiconductor wafer processing chamber e.g., a plasma etch reactor, that benefits from the use of the present invention. Although a plasma etch reactor is shown as an example of the type of semiconductor wafer processing chamber that may benefit from the use of the thermal shim of the present invention, those skilled in the art will understand that any semiconductor wafer processing chamber or system that supports the wafer on a pedestal or other substrate support and requires a particular temperature profile across the wafer may benefit from the thermal shim of the present invention. As such, the embodiment showing a plasma etch reactor should not be considered limiting of the scope of the invention.

The etch reactor 100 comprises a volume 114 defined by a dome 104, sidewalls 115 and a bottom 118. External to the dome 104 and proximate to its surface is an antenna 102. During etching, a reactive gas is supplied to the volume 114 and the antenna is energized to form a plasma in the volume 114. In a process for etching silicon wafers, the reactant gas is, for example, sulfur hexafluoride (SF₆). Other fluorine-based gases may be used to etch silicon.

A wafer 112 is supported proximate the etchant plasma upon a wafer support 106. The wafer support 106 comprises a heat exchanger pedestal 116 (also referred to as a cooling plate), a thermal shim 108, and an electrostatic chuck 110 (or other wafer retention device). An electrostatic chuck 110 is depicted as an illustrative example of one type of wafer retention device. Other wafer retention devices such as mechanical clamp, vacuum chuck, and the like may be used.

When processing a wafer, the temperature of the wafer is important to achieving effective processing. In addition, the temperature profile across a wafer is important to achieving uniform processing. For example, in an etch process, the etch rate is very dependent upon temperature. Thus, the absolute temperature should be held constant and the temperature profile should be flat. As such, the heat exchanger pedestal 116 draws heat from the wafer through the electrostatic chuck 110 and the thermal shim 108 and removes the heat from the reactor. The heat exchanger pedestal 116 generally comprises a thermally conductive pedestal 120 and a heat exchanger element 122. The heat exchanger element 122 is coupled to a heat exchanger 124 that is external to the reactor. In one embodiment, the heat exchanger 124 removes heat from the heat exchanger element 122. In a conventional manner, the pedestal 120 is fabricated of a thermally conductive material such as aluminum to conduct heat to the heat exchanger element 122. The element 122 is typically a hollow conduit that carries a fluid to and from the heat exchanger 124. The fluid retains the heat from the pedestal 120 and the heat exchanger 124 removes the heat from the fluid. Although one simple embodiment of a heat exchanger is described, those skilled in the art will understand that any number of heat exchanger techniques may be used to remove heat from the pedestal 120. In an alternative embodiment, the heat exchanger pedestal 120 may contain an element 122 that heats the wafer. For purposes of this invention, the pedestal 120 should be considered as being either a heat source or a heat sink. Any of the various heat exchanger techniques that either heat or cool the wafer may find the present invention useful in forming a specific thermal profile for the wafer.

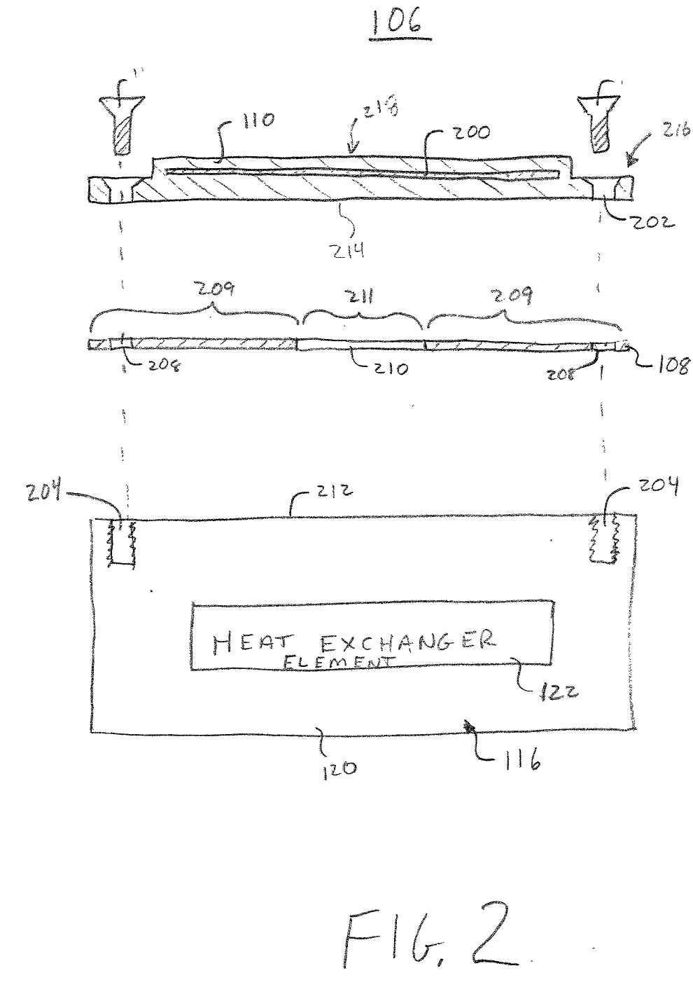

FIG. 2 depicts an exploded cross-sectional view of one embodiment of the wafer support 106. The wafer support 106 comprises the heat exchanger pedestal 116, the thermal shim 108 and the electrostatic chuck 110. The electrostatic chuck 110 comprises an electrode 200 a wafer support region 218, and a peripheral flange 216. The electrode 200 is embedded in the wafer support region 218. A number of bores 202 are formed in the peripheral flange 216. These bores 2102 are used for mounting the chuck 110 to the pedestal 120.

A thermal shim 108 is located between the electrostatic chuck 110 and the heat exchanger pedestal 116. The thermal shim 108 comprises a substantially flat, thermally conductive material such as aluminum or copper. Alternatively, the shim 108 may have a corrugated surface. The shim 108 comprises a high thermally conductive region 209 and a low thermally conductive region 211. In one embodiment of the invention, the high thermally conductive region 209 is formed from metallic material, while the low thermally conductive region 211 is a hole in the metallic material. In other embodiments of the shim 108, the low thermally conductive region may comprise a low conductivity material such as an insulator. In further embodiments of the invention, the shim 108 may be solid with a contour in the material composition such as contoured alloys to allow for varying thermal conductivity across the shim. In a further embodiment, the center may be thermally conductive and the edge region thermally insulative. In any of the embodiments, the intent is to create a barrier that has a thermal conductivity profile such that the flow of heat from the wafer to the pedestal has a particular profile.

The thermal shim is sandwiched between the top planar surface 212 of the heat exchanger pedestal 116 and the bottom 214 of the electrostatic chuck 110. Holes 208 are bored near the edge of the shim 108 to match the holes 202 bored in the electrostatic chuck 110 and threaded bores 204 that are formed in the heat exchanger pedestal 116. Bolts 220 pass through the bores 202, through the bores 208, and couple to the threaded bores 204 in the heat exchanger pedestal 116. Tightening the bolts 220 creates a good thermal path from the chuck 110, through the shim 108 and into the pedestal 116.

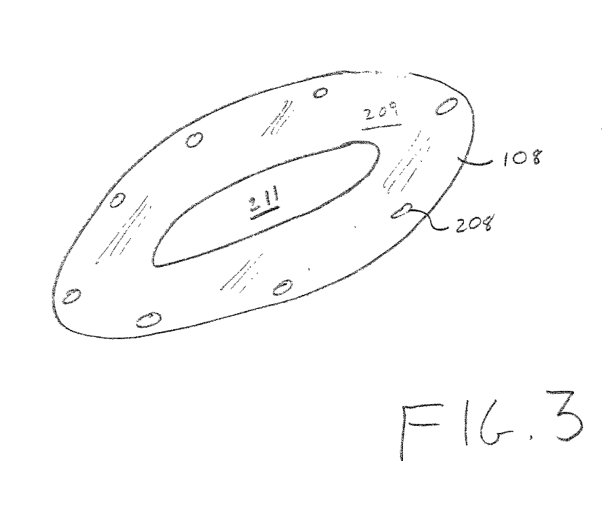

FIG. 3 shows a perspective view of one embodiment of the thermal shim 108 of the present invention. The shim 108 has a low thermally conductive region 211 and a high thermally conductive region 209. In this particular embodiment, the region 209 is annular and circumscribes the region 211. The particular arrangement, position and shape of the regions 209 and 211 depends on the desired thermal conductivity profile.

In one specific embodiment of the invention, the thermal shim is used in a plasma etch reactor such as the DPS silicon etch reactor manufactured by Applied Materials, Inc. of Santa Clara, Calif. The thermal shim is fabricated of aluminum having a thickness of about 0.008 inches (200 μm) and a outer diameter of about 9 inches (220 mm) and an inner diameter of the low thermally conductive region 211 of about 7 inches (180 mm). As such, the high thermally conductive region has a width of about 2 inches (50 mm). This shim provides a relatively flat thermal profile as compared to the profile produced by a uniform sheet of aluminum. As a result of the improved thermal profile, the center-to-edge etch results is substantially improved such that the critical dimension (CD) of the center trenches is about 90 microns and the CD of the edge trenches is about 95 microns. In comparison, a uniform sheet provides a center trench CD of 68 microns and an edge trench CD of 103 microns. Clearly, the improved thermal profile provided by the present invention improves the etch uniformity across the wafer.

While foregoing is directed to the preferred embodiment of the present invention, other and further embodiments of the invention may be devised without departing from the basic scope thereof, and the scope thereof is determined by the claims that follow.

1. A thermal shim adapted for positioning between a wafer retention device and a pedestal, where said thermal shim comprises a low thermally conductive region and a high thermally conductive region.

2. The thermal shim of claim 1 wherein said low thermally conductive region is centrally located within the high thermally conductive region.

3. The thermal shim of claim 1 wherein said low thermally conductive region is a hole.

4. The thermal shim of claim 1 wherein said high thermally conductive region is in the shape of an annulus.

5. The thermal shim of claim 1 wherein the high thermally conductive region is fabricated of a metallic material.

6. The thermal shim of claim 5 wherein said metallic material is aluminum or copper.

7. The thermal shim of claim 1 wherein the thermal shim is fabricated of a corrugated material.

8. The thermal shim of claim 1 wherein the low thermally conductive region is an insulator.

9. A wafer support comprising:
a heat exchanger pedestal having a top surface;
a thermal shim having a high thermally conductive region and a low thermally conductive region; and
a wafer retention device having a bottom surface, wherein the thermal shim is located between the bottom surface of the wafer retention device and the top surface of the heat exchanger pedestal.

10. The thermal shim of claim 9 wherein said low thermally conductive region is centrally located within the high thermally conductive region.

11. The wafer support of claim 9 wherein said low thermally conductive region is a hole.

12. The wafer support of claim 9 wherein said high thermally conductive region is in the shape of an annulus.

13. The wafer support of claim 9 wherein the high thermally conductive region is fabricated of a metallic material.

14. The wafer support of claim 13 wherein said metallic material is aluminum or copper.

15. The wafer support of claim 9 wherein the thermal shim is fabricated of a corrugated material.

16. The wafer support of claim 9 wherein the low thermally conductive region is an insulator.

17. An etch reactor having a wafer support, wherein said wafer support comprises:
a heat exchanger pedestal having a top surface;
a thermal shim having an annular shaped a high thermally conductive region and a centrally located hole defined by the high thermally conductive region; and
an electrostatic chuck having a bottom surface, wherein the thermal shim is located between the bottom surface of the electrostatic chuck and the top surface of the heat exchanger pedestal.

18. The etch reactor of claim 1 where the thermal shim is fabricated of metal.

19. The etch reactor of claim 1 wherein the thermal shim is corrugated.

20. A wafer support comprising:
a heat exchanger pedestal having a top surface;
means for controlling thermal conductivity having a high thermally conductive region and a low thermally conductive region; and
a wafer retention device having a bottom surface, wherein the means for controlling thermal conductivity is located between the bottom surface of the wafer retention device and the top surface of the heat exchanger pedestal.

21. The wafer support of claim 20 wherein said means for controlling the thermal conductivity is a thermal shim.
